(19) United States
(12) Patent Application Publication
(10) Pub. No.: US 2007/0096821 A1
(43) Pub. Date: May 3, 2007

(54) Wide-band amplifier

(75) Inventors: Jae-young Ryu, Suwon-si (KR); Hyun-koo Kang, Yongin-si (KR); Dae-yeon Kim, Suwon-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/580,898

(22) Filed: Oct. 16, 2006

(30) Foreign Application Priority Data
Nov. 3, 2005 (KR) 10-2005-0105000

(51) Int. Cl. H03F 3/16

(52) U.S. Cl. 330/277

(57) ABSTRACT

An amplifier that achieves impedance matching in a wide frequency band is provided. The wide-band amplifier includes a first n-type metal oxide semiconductor (NMOS) transistor which receives an input signal; a second NMOS transistor which buffers a signal amplified by the first NMOS transistor; a third NMOS transistor which amplifies a signal supplied from a source of the first NMOS transistor; and an output terminal which outputs a signal obtained by combining the signal buffered by the second NMOS transistor with the signal amplified by the third NMOS transistor.

### CROSS-REFERENCE TO RELATED APPLICATION

This application claims priority from Korean Patent Application No. 10-2005-0105000 filed on Nov. 3, 2005 in the Korean Intellectual Property Office, the disclosure of which is incorporated herein by reference in its entirety.

### BACKGROUND OF THE INVENTION

1. Field of the Invention

Apparatuses consistent with the present invention relate to a wide-band amplifier, and more particularly, to a wide-band amplifier that is designed to achieve impedance matching in a wide-band frequency range.

2. Description of the Related Art

In general, an amplifier is an essential circuit block of an RF device. FIG. 1 shows an amplifier circuit according to the related art.

In FIG. 1, a cascade topology representative of an amplifier configuration is shown, and the cascade topology includes a common source N-type Metal Oxide Semiconductor (NMOS) transistor 105 and a common gate NMOS transistor 110.

An inductor 107 for input impedance matching of an amplifier 100 is coupled between a source terminal of the common source NMOS transistor 105 and a ground terminal, and a gate terminal of the common source NMOS transistor 105 is an input terminal.

Further, a gate terminal of the common gate NMOS transistor 110 is coupled to a bias voltage source, and a drain terminal of the common gate NMOS transistor 110 is an output terminal. Furthermore, a load inductor 112 is coupled between the drain terminal of the common gate NMOS transistor 110 and a DC voltage source V_{DD} so as to adjust the output impedance of the amplifier 100.

In FIG. 1, if input impedance at the input terminal of the amplifier 100 is set to Zᵢₙ; Zᵢₙ is expressed by Equation 1:

$${Z}_{in} = ( \frac{1}{j {wC}_{gs}} + j {wL}_{s} ) + {g}_{m} \times \frac{{L}_{s}}{{C}_{gs}} \qquad ( 1 )$$

C_{gs} represents a capacitance between the gate terminal and the source terminal of the common source NMOS transistor 105, and gₘ represents the transconductance of the common source NMOS transistor 105.

In Equation 1, in order to accomplish input impedance matching at 50 Ω, the following conditions must be satisfied:

$$\begin{matrix}\frac{1}{{wC}_{gs}} - {wL}_{s} = 0 \\ and {g}_{m} \times \frac{{L}_{s}}{{C}_{gs}} = 50\end{matrix}$$

Therefore, one matching circuit is not enough to make a frequency bandwidth, in which input impedance matching is achieved for more than 10% of a center frequency.

The output impedance of the output terminal is determined by the output resistance of the common gate NMOS transistor 110 and the load inductor 112.

Assuming that the output impedance is Zout, Zout can be expressed as: Zout=(rₒ∥jwL_{L}). When rₒ is very large, Zₒᵤₜ becomes jwL_{L}, and as a result, wide-band matching is difficult.

In other words, since the input impedance and the output impedance are determined on the basis of frequencies, a matching frequency band, in which the S-parameter S11 corresponding to the input impedance and the S-parameter S22 corresponding to the output impedance are both less than −10 dB, is narrow, as shown in FIG. 2.

FIG. 2 is a graph showing a simulation result of the circuit shown in FIG. 1. In FIG. 2, the center frequency is 2.35 GHz, and the matching frequency band in which the S-parameters S11 and S22 are both less than −10 dB at the input and output terminals is about 10% of the center frequency.

Further, according to the related art shown in FIG. 1, the inductor 107 is provided at the source terminal of the common source NMOS transistor 105 for matching of the circuit, and the inductor 112 is used as a load in order to obtain a gain. Therefore, the layout size of the whole circuit increases, and thus the cost increases.

For this reason, an amplifier is required that can achieve matching in a wider frequency band without increasing the size of the entire circuit.

### SUMMARY OF THE INVENTION

An aspect of the present invention is to provide an amplifier that achieves impedance matching in a wide frequency band.

Another aspect of the present invention is to provide an amplifier that achieves wide-band impedance matching and enough gain without using elements such as an inductor.

Aspects of the present invention are not limited to those mentioned above, and other aspects of the present invention will be apparently understood by those skilled in the art through the following description.

In order to achieve the above and other aspects, according to an exemplary embodiment of the present invention, a wide-band amplifier includes a first n-type metal oxide semiconductor (NMOS) transistor which receives an input signal; a second NMOS transistor which buffers a signal amplified by the first NMOS transistor; a third NMOS transistor which amplifies a signal supplied from a source of the first NMOS transistor; and an output terminal which outputs a signal obtained by combining the signal buffered by the second NMOS transistor with the signal amplified by the third NMOS transistor.

Further, according to another exemplary embodiment of the present invention, a wide-band amplifier includes an input module which receives an input signal to be amplified, and provides signals corresponding to the input signal through different terminals, and an output terminal which combines the signals supplied from the input module through different circuit paths.

### BRIEF DESCRIPTION OF THE DRAWINGS

The above and other aspects, of the present invention will become more apparent by describing in detail certain exemplary embodiments thereof with reference to the attached drawings, in which:

FIG. 1 is a circuit diagram showing the configuration of an amplifier according to the related art;

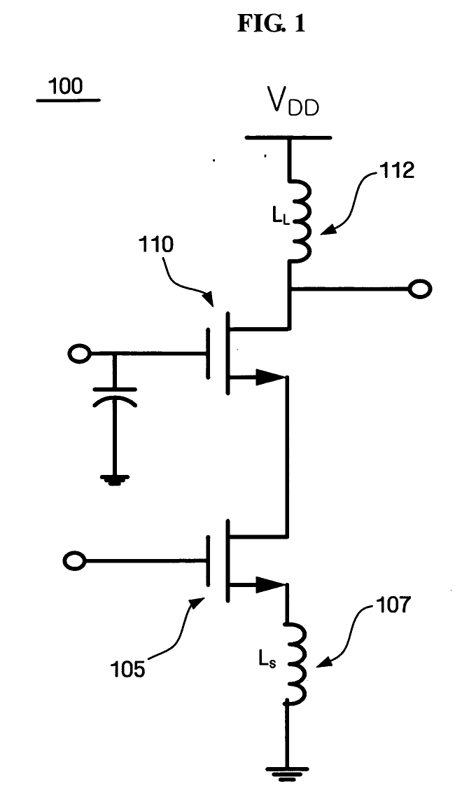

FIG. 2 is a graph showing the simulation result of the circuit of FIG. 1;

FIG. 3 is a block diagram showing an example of a wide-band amplifier according to an exemplary embodiment of the present invention;

FIG. 4 is a circuit diagram showing the configuration of the wide-band amplifier according to an exemplary embodiment of the present invention; and

FIG. 5 is a graph showing a simulation result of the wide-band amplifier according to an exemplary embodiment of the invention.

### DESCRIPTION OF EXEMPLARY EMBODIMENTS OF THE PRESENT INVENTION

Advantages and features of the present invention and methods of accomplishing the same may be understood more readily by reference to the following detailed description of exemplary embodiments of the present invention and the accompanying drawings. The present inventive concept may, however, be embodied in many different forms and should not be construed as being limited to the exemplary embodiments set forth herein. Rather, these exemplary embodiments are provided so that this disclosure will be thorough and complete and will fully convey the concept of the invention to those skilled in the art, and the present invention will only be defined by the appended claims. Like reference numerals refer to like elements throughout the specification.

The present inventive concept is described hereinafter with reference to flowchart illustrations of user interfaces, methods, and computer program products according to exemplary embodiments of the invention. It will be understood that each block of the flowchart illustrations, and combinations of blocks in the flowchart illustrations, can be implemented by computer program instructions. These computer program instructions can be provided to a processor of a general-purpose computer, special purpose computer, or other programmable data processing apparatus to produce a machine, such that the instructions, which execute via the processor of the computer or other programmable data processing apparatus, create means for implementing the functions specified in the flowchart block or blocks.

These computer program instructions may also be stored in a computer usable or computer-readable memory that can direct a computer or other programmable data processing apparatus to function in a particular manner, such that the instructions stored in the computer usable or computer-readable memory produce an article of manufacture including instruction means that implement the function specified in the flowchart block or blocks.

The computer program instructions may also be loaded onto a computer or other programmable data processing apparatus to cause a series of operational steps to be performed on the computer or other programmable apparatus to produce a computer implemented process such that the instructions that execute on the computer or other programmable apparatus provide steps for implementing the functions specified in the flowchart block or blocks.

And each block of the flowchart illustrations may represent a module, segment, or portion of code, which comprises one or more executable instructions for implementing the specified logical function(s). It should also be noted that in some alternative implementations, the functions noted in the blocks may occur out of the order. For example, two blocks shown in succession may in fact be executed substantially concurrently or the blocks may sometimes be executed in the reverse order, depending upon the functionality involved.

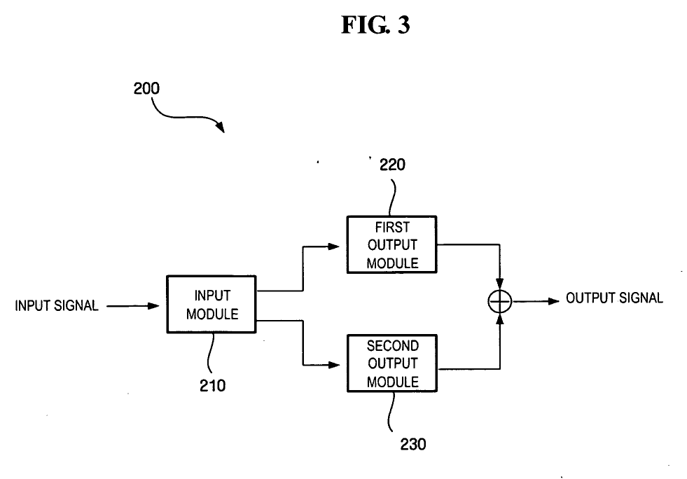

FIG. 3 is a block diagram showing an example of a wide-band amplifier according to an exemplary embodiment of the present invention.

Referring to FIG. 3, a wide-band amplifier 200 according to an exemplary embodiment of the present invention includes an input module 210, a first output module 220, and a second output module 230.

The term “module”, as used herein, means, but is not limited to, a software or hardware component, such as a Field Programmable Gate Array (FPGA) or an Application Specific Integrated Circuit (ASIC), which performs certain tasks. A module may advantageously be configured to reside on an addressable storage medium and configured to execute on one or more processors. Thus, a module may include, by way of example, components, such as software components, object-oriented software components, class components and task components, processes, functions, attributes, procedures, subroutines, segments of program code, drivers, firmware, microcode, circuitry, data, databases, data structures, tables, arrays, and variables. The functionality provided for in the components and modules may be combined into fewer components and modules or further separated into additional components and modules.

The input module 210 receives an input signal to be amplified, and outputs signals corresponding to the input signal to the first output module 220 and the second output module 230 through two different terminals, respectively.

The first output module 220 and the second output module 230 output signals corresponding to the signals provided from the input module 210. The output signals of the first and second output modules 220 and 230 are combined to form one output signal of the wide-band amplifier 200.

In other words, in the wide-band amplifier 200 according to an exemplary embodiment of the present invention, two signals corresponding to an input signal pass through two different paths to be combined into one signal, and the combined signal is then output as an amplified signal.

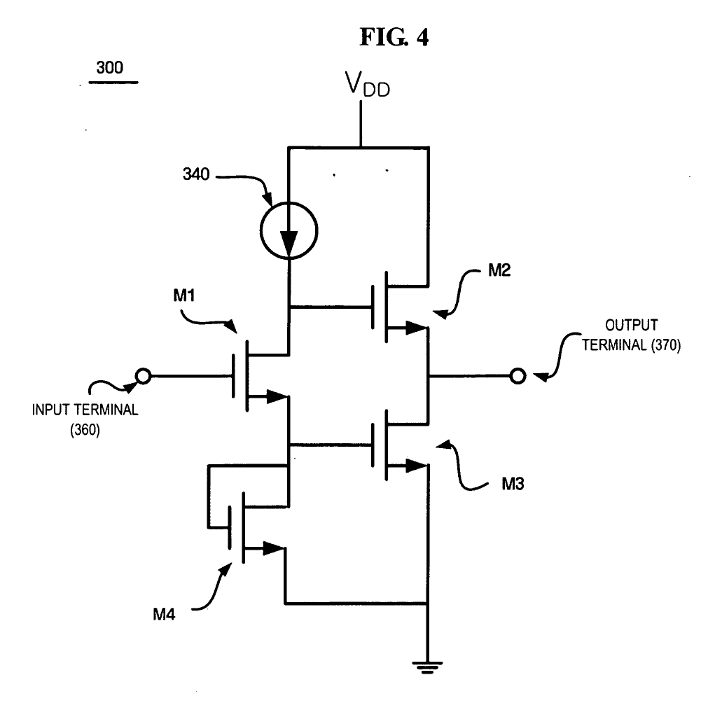

FIG. 4 is a circuit diagram showing the configuration of the wide-band amplifier according to the exemplary embodiment of the present invention shown in FIG. 3.

Referring to FIG. 4, a wide-band amplifier 300 includes an NMOS transistor M1 simultaneously performing functions of a common source and a common drain; a common drain NMOS transistor M2 for buffering a signal amplified by the NMOS transistor M1; and an NMOS transistor M3 for amplifying a signal supplied from a source of the NMOS transistor M1.

Further, the wide-band amplifier 300 includes a current source 340 for operating the NMOS transistor M1 and an NMOS transistor M4 that is connected in the form of a diode connection to sink a current flowing from the current source 340 to the NMOS transistor M1.

Furthermore, in FIG. 4, V_{DD} denoting a DC power source voltage, a signal input terminal 360, and a signal output terminal 370 are shown.

Comparing the circuit of FIG. 4 with the configuration of FIG. 3, the input module 210, the first output module 220, and the second output module 230 of FIG. 3 may correspond to the NMOS transistor M1, the common drain NMOS transistor M2, and the NMOS transistor M3 of FIG. 4, respectively.

The wide-band amplifier 300 of FIG. 4 has two signal paths, similar to the wide-band amplifier of FIG. 3.

The first signal path is a common source-common drain signal path formed by the NMOS transistor M1 and the common drain NMOS transistor M2, which is based on a common source-source follower configuration.

The second signal path is a common drain-common source signal path formed by the NMOS transistor M1 and the NMOS transistor M3, which is based on a source follower-common source configuration.

The two paths are joined together at the output terminal 370. The phases of the signals output from the two paths are equal to each other, and thus the signal gain at the output terminal 370 becomes twice.

Assuming that the output impedance of the output terminal 370 of the wide-band amplifier 300 shown in FIG. 4 is Zₒᵤₜ, Zₒᵤₜ can be expressed as follows: Zout=(rₒ∥1/gₘ).

Here, rₒ denotes a resistance component when looking at the drain terminal side of the NMOS transistor M3 from the output terminal 370, 1/gₘ represents a resistance component when looking at the source terminal side of the common drain NMOS transistor M2 from the output terminal 370, and gₘ represents the transconductance of the common drain NMOS transistor M2.

In this case, when rₒ is very large, Zₒᵤₜ can be expressed by Equation 2:

$$\begin{matrix}{Z}_{out} ≅ \frac{1}{{g}_{m}} \\ ≅ 50 Ω\end{matrix} \qquad ( 2 )$$

Therefore, the impedance matching of the output impedance of the wide-band amplifier 300 is achieved regardless of a frequency by the current flowing through the common drain NMOS transistor M2 and the NMOS transistor M3. As a result, impedance matching can be achieved in a wider frequency band.

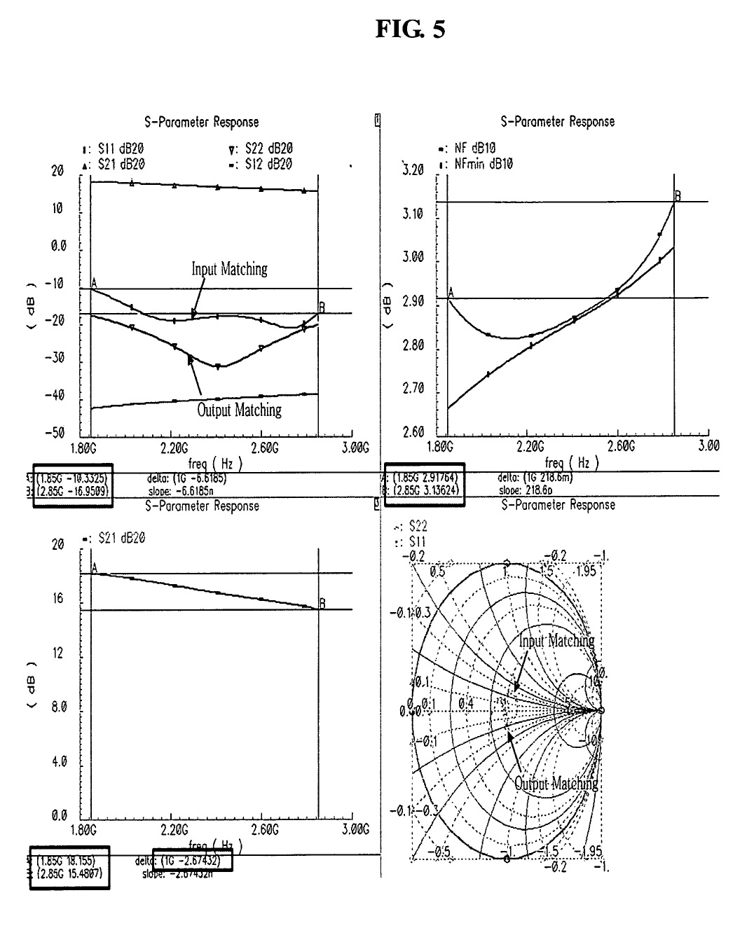

FIG. 5 is a graph showing a simulation result of an exemplary embodiment of the present invention. More specifically, FIG. 5 shows a result obtained by simulating the circuit shown in FIG. 4 under conditions that the center frequency is 2.35 GHz and the span is 1 GHz. For reference, the voltage applied to the circuit shown in FIG. 4 is 1.8 V and the current consumption thereof is 5.6 mA.

Referring to FIG. 5, an S-parameter S11 corresponding to the input impedance and an S-parameter S22 corresponding to the output impedance are both smaller than −10 dB in the frequency band of 1 GHz.

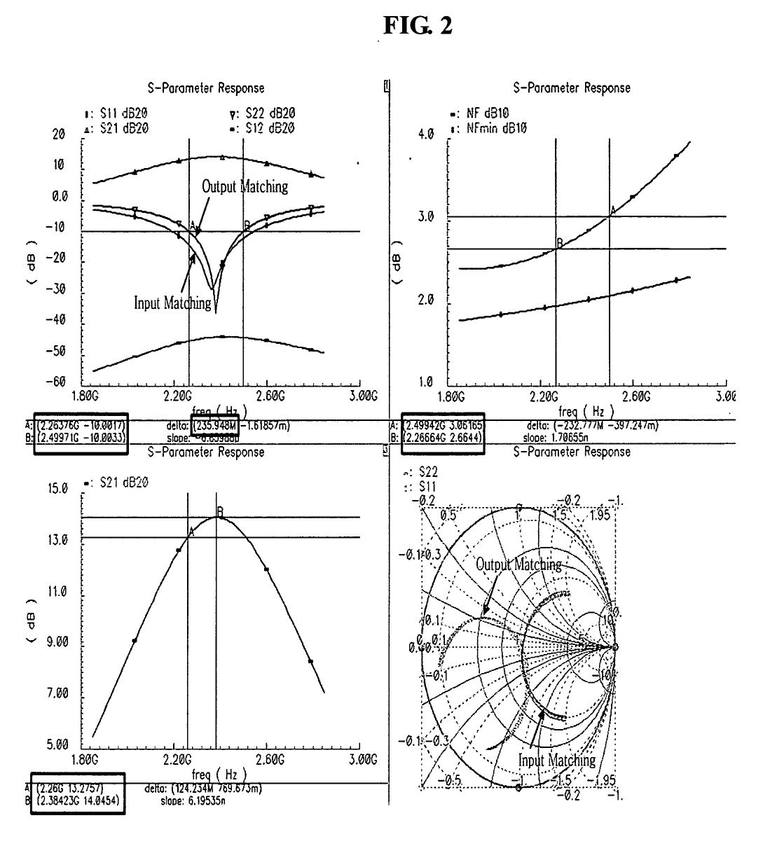

That is, in the wide-band amplifier 300 according to an exemplary embodiment of the present invention, an input impedance and an output impedance are smaller than −10 dB in a wider frequency band, as compared to the S-parameters S11 and S22 shown in FIG. 2.

As can be seen from FIGS. 2 and 5, according to an exemplary embodiment of the present invention, the noise figure is the same, the gain is increased by 4 dB, and the variation of the gain is 2.7 dB in a band of 1 GHz, as compared to the amplifier according to the related art. Further, as can be seen from the Smith charts of FIGS. 2 and 5, according to the present invention, the impedance matching is accomplished in the vicinity of 50 Ω.

The results of comparing the graphs of FIGS. 2 and 5 are shown in Table 1:

TABLE 1

| | | | Present | |
|---|---|---|---|---|
| Parameter | Unit | Related art | Invention | Remark |
| Matching | MHz | 236 | 1000 or more | Fcenter = 2.35 GHz |
| Band | | | | S11, S22 <− 10 dB |
| Power Gain | dB | 13.9 | 16.8 | @ Freq. = 2.35 GHz |
| Noise | dB | 2.82 | 2.85 | @ Freq. = 2.35 GHz |
| Figure | | | | |

Although the present inventive concept has been described in connection with the exemplary embodiments of the present invention, it will be apparent to those skilled in the art that various modifications and changes may be made without departing from the scope and spirit of the invention. Therefore, it should be understood that the above exemplary embodiments are not limitative, but illustrative in all aspects.

According to the present inventive concept, a wide-band amplifier can achieve impedance matching in a wide frequency band in which a matching frequency band is 50% or more of a center frequency, thereby capable of being applied to wide-band systems such as a tuner, a Ultra Wide Band (UWB) device, a Wireless Local Area Network (WLAN), or other similar application.

Further, according to the present inventive concept, the wide-band amplifier does not use any inductor to obtain impedance matching and gain, thereby reducing the layout size of the amplifier circuit and the cost.

Furthermore, according to the present inventive concept, the wide-band amplifier has two signal paths to make the final signals thereof be in phase, thereby increasing the gain.

What is claimed is:

1. A wide-band amplifier comprising:
a first n-type metal oxide semiconductor (NMOS) transistor which receives an input signal;
a second NMOS transistor which buffers a signal amplified by the first NMOS transistor;
a third NMOS transistor which amplifies a signal supplied from a source of the first NMOS transistor; and
an output terminal which outputs a signal obtained by combining the signal buffered by the second NMOS transistor with the signal amplified by the third NMOS transistor.

2. The wide-band amplifier of claim 1, wherein an in-phase signal is output from the output terminal.

3. The wide-band amplifier of claim 1, further comprising:
a current source which supplies current to the first NMOS transistor; and
a fourth NMOS transistor which sinks a current that is supplied from the current source and flows through the first NMOS transistor.

4. The wide-band amplifier of claim 3, wherein the fourth NMOS transistor is formed in a diode connection manner.

5. The wide-band amplifier of claim 1, wherein the first NMOS transistor operates as a common source and a source follower.

6. The wide-band amplifier of claim I, wherein the first NMOS transistor and the second NMOS transistor are formed in a common source-common follower configuration.

7. The wide-band amplifier of claim 1, wherein the first NMOS transistor and the third NMOS transistor are formed in a source follower-common source configuration.

8. The wide-band amplifier of claim 1, wherein an output impedance at the output terminal is independent of a frequency of the input signal received by the first NMOS transistor.

9. The wide-band amplifier of claim 1, wherein an output impedance at the output terminal is expressed by a transconductance of the second NMOS transistor.

10. A wide-band amplifier comprising:
an input module which receives an input signal to be amplified, and provides signals corresponding to the input signal through different terminals, and
an output terminal which combines the signals supplied from the input module through different circuit paths.

11. The wide-band amplifier of claim 10, further comprising:
first and second output modules which receive the input signal supplied from the input module and output signals corresponding to the received signal to the output terminal.

12. The wide-band amplifier of claim 10, wherein the signal output from the output terminal is an in-phase signal.

13. The wide-band amplifier of claim 10, wherein an output impedance at the output terminal is independent of a frequency of the input signal received by the input module.
